(19) United States
(12) Patent Application Publication
(10) Pub. No.: US 2018/0112321 A1
(43) Pub. Date: Apr. 26, 2018

(54) ACIDIC COPPER PLATING SOLUTION, ACIDIC COPPER PLATED PRODUCT, AND METHOD FOR PRODUCING SEMICONDUCTOR DEVICE

(71) Applicant: FINE FEATURE ELECTRODEPOSITION RESEARCH INSTITUTE, INC., Osaka (JP)

(72) Inventor: Kazuo KONDO, Osaka (JP)

(73) Assignee: FINE FEATURE ELECTRODEPOSITION RESEARCH INSTITUTE, INC., Osaka (JP)

(21) Appl. No.: 15/577,949

(22) PCT Filed: Nov. 21, 2016
(86) PCT No.: PCT/JP2016/084499

§ 371 Date: Nov. 29, 2017

(30) Foreign Application Priority Data
Nov. 26, 2015 (JP) PCT/JP2015/083280

(51) Int. Cl. C25D 3/38; C25D 7/12; H01L 21/768; H01L 21/288; H01L 23/532; H05K 3/18; H05K 3/06; H05K 1/09; H01L 21/306

(52) U.S. Cl. CPC C25D 3/38; C25D 7/12; H01L 21/76898; H01L 21/2885; H05K 2203/0723; H05K 3/188; H05K 3/064; H05K 1/09; H01L 21/30625; H01L 23/53228

(57) ABSTRACT

The acidic copper plating solution of the present invention includes: a first additive including a cationic polymer; at least one second additive selected from the group consisting of 2-mercapto-5-benzimidazole sulfonic acid, sodium 2-mercapto-5-benzimidazole sulfonate dihydrate, ethylene thiourea, and partial 2-mercapto-5-benzimidazole sulfonate of poly(diallyldimethylammonium chloride); and a third additive including a sulfur atom-containing organic compound, the acidic copper plating solution having a copper concentration of 10 to 60 g/L and a sulfuric acid concentration of 10 to 200 g/L, and containing chloride ions of in an amount of 90 mg/L or less. The acidic copper plating solution is capable of producing an acidic copper plated product having low thermal expansion property.

### TECHNICAL FIELD

The present invention relates to an acidic copper plating solution, an acidic copper plated product, and a method for producing a semiconductor device.

### BACKGROUND ART

As one of techniques that overcome a limit of miniaturization of LSI chips, a three-dimensional stacking technique is being studied in which a large number of LSI chips are stacked into one package. In the three-dimensional stacking technique, an upper transistor and a lower transistor are connected by a through silicon via (hereinafter abbreviated as TSV). A via middle process, which is one of processes for preparation of TSV, is a process in which TSV is formed before a wiring process. In the via middle process, a non-through via is formed on a silicon substrate provided with a transistor, and the non-through via is filled with copper by electroplating using an acidic copper plating solution. Further, the silicon substrate is thinned by CMP to expose the bottom of the non-through via, and an insulating oxide film is formed during formation of a wiring layer.

However, in the via middle process, heating to 400 to 600° C. is performed in formation of the insulating oxide film, and since the thermal expansion coefficient of copper is larger than that of silicon, there is the problem that copper in TSV expands (hereinafter, referred to as pumping), leading to breakage of an upper wiring layer (e.g. Non-Patent Documents 1, 2 and 3). Thus, the three-dimensional stacking technique has not been put into practical use.

In order to prevent the pumping of TSV, for example, a method has been proposed in which a process is repeated multiple times in which prepared TSV is heated, then cooled, and flattened by CMP (e.g. Non-Patent Documents 2, 3 and 4). However, this method has the problem that the number of heating steps and costly CMP steps increases, resulting in an increase in production cost.

### PRIOR ART DOCUMENTS

### Non-Patent Documents

Non-Patent Document 1: Che, F. X. et al., “Numerical and experimental study on Cu protrusion of Cu filled through-silicon vias (TSV)”, Proc. 3DIC, pp. 1-6, 2011
Non-Patent Document 2: Redolfi, A. et al., “Implementation of an industry compliant, 5×50 μm, via-middle TSV technology on 300 mm wafers”, Proc. ECTC. pp. 1384-1388, 2011
Non-Patent Document 3: Solid State TECHNOLOGY, Dec. 15, 2010, “Cu protrusion, keep out zones highlight 3D talk at IEDM”, URL, http://www.electroiq.com/articles/ap/2010/12/cu-protrusion-keep-out.html
Non-Patent Document 4: De Messemaeker, J. et al., “Correlation between Cu microstructure and TSV Cu pumping”, Proc. ECTC IEEE64th, pp. 613-619, 2014.

### SUMMARY OF THE INVENTION

### Problems to be Solved by the Invention

The present invention has been made in view of the above-mentioned conventional problems, and an object of the present invention is to provide an acidic copper plating solution capable of suppressing thermal expansion of a plated product, an acidic copper plated product obtained using the plating solution, and a method for producing a semiconductor device using the plating solution.

### Means for Solving the Problem

As a result of extensively conducting studies for solving the above-mentioned problems, the present inventor has developed an acidic copper plating solution capable of producing an acidic copper plated product having a thermal expansion coefficient smaller than that of conventional plated copper, and found that thermal expansion of the acidic copper plated product can be suppressed.

That is, the acidic copper plating solution of the present invention includes: a first additive including a cationic polymer; at least one second additive selected from the group consisting of 2-mercapto-5-benzimidazole sulfonic acid, sodium 2-mercapto-5-benzimidazole sulfonate dihydrate, ethylene thiourea, and partial 2-mercapto-5-benzimidazole sulfonate of poly(diallyldimethylammonium chloride); and a third additive including a sulfur atom-containing organic compound, the acidic copper plating solution having a copper concentration of 10 to 60 g/L and a sulfuric acid concentration of 10 to 200 g/L, and containing chloride ions of in an amount of 90 mg/L or less.

In addition, the acidic copper plated product of the present invention has a lattice constant of more than 3.6147 Å at room temperature.

In addition, a method for producing a semiconductor device according to the present invention includes a step of preparing a through silicon via, the through silicon via preparing step including the steps of: forming a non-through via on one main surface of a silicon substrate with a transistor formed on the one main surface; plating at least the non-through via with copper by electroplating using the acidic copper plating solution according to claim 1; and forming the through silicon via by polishing the other main surface of the silicon substrate to expose copper filled into the non-through via.

In addition, another method for producing a semiconductor device according to the present invention includes the step of preparing a through silicon via, the through silicon via preparing step including the steps of: forming a through via hole on one main surface of a silicon substrate with a transistor and a wiring layer formed on the other main surface; and plating the through via hole with copper by electroplating using the acidic copper plating solution of the present invention.

In addition, a method for producing a printed circuit board according to the present invention includes the steps of: forming an opening section on an upper surface of a substrate having a copper foil on a lower surface thereof, the opening section extending to the copper foil; forming a conductive underlayer on the upper surface of the substrate and the opening section; then forming a copper wiring layer on a surface of the underlayer by electroplating using the acidic copper plating solution according to claim 1; and patterning the copper wiring layer.

In addition, another method for producing a printed circuit board according to the present invention includes the steps of: forming an opening section on an upper surface of a substrate having a copper foil on a lower surface thereof, the opening section extending to the copper foil; forming a conductive underlayer on the upper surface of the substrate and the opening section; forming a resist layer having a predetermined shape on the underlayer; then forming a copper wiring layer on a surface of the underlayer exposed from the resist layer by electroplating using the acidic copper plating solution according to claim 1; and then removing the resist layer and the underlayer.

### Effects of the Invention

According to the present invention, it is possible to provide an acidic copper plating solution capable of suppressing thermal expansion of an acidic copper plated product. By using the acidic copper plating solution of the present invention, for example, pumping of TSV can be prevented without increasing the number of heating steps and CMP steps, and therefore a three-dimensional stacking technique using TSV can be put into practical use.

### BRIEF DESCRIPTION OF DRAWINGS

FIG. 1 is a graph showing one example of a result of measuring a thermal expansion coefficient of an acidic copper plated product produced using an acidic copper plating solution of the present invention.

FIG. 2 is a scanning electron micrograph showing an example of a cross-sectional structure of TSV produced using the acidic copper plating solution of the present invention.

FIG. 3A is a scanning electron micrograph showing the surface states of a comparative TSV sample at room temperature (left side) and after heating (right side).

FIG. 3B is a scanning electron micrograph showing the surface states of a TSV sample according to the present invention at room temperature (left side) and after heating (right side).

FIG. 4A is a scanning electron micrograph showing the surface state of the TSV sample according to the present invention after heating six times.

FIG. 4B is a scanning electron micrograph showing the surface state of a comparative TSV sample after heating six times.

FIG. 5 is a graph showing another example of a result of measuring a thermal expansion coefficient of an acidic copper plated product produced using an acidic copper plating solution of the present invention.

FIG. 6 is a scanning electron micrograph showing a change in structure associated with heating for an acidic copper plated product produced using the acidic copper plating solution of the present invention, where pictures a, b, c and d show results of observation at 203° C., 310° C., 350° C. and 450° C., respectively.

FIG. 7 is a scanning electron micrograph of a portion used for field emission Auger electron spectroscopy (FEAES) analysis for a sample of an acidic copper plated product produced using the acidic copper plating solution of the present invention and heated to 450° C.

FIG. 8 is a view showing a result of FEAES analysis of a black spot in the photograph of FIG. 7.

FIG. 9 is a view showing a result of FEAES analysis of a portion indicated by reference numeral 2 as a region other than the black spot in the photograph of FIG. 7.

FIG. 10 is a view showing an example of a result of X-ray diffraction of a sample of an acidic copper plated product produced using the acidic copper plating solution of the present invention and heated to 450° C.

FIG. 11 is a schematic view showing a structure of a measurement cell used for measuring a thermal expansion coefficient.

FIG. 12 is a schematic view showing a structure of a high-temperature sample stage used for observation of a pumping phenomenon of TSV.

### BEST MODE FOR CARRYING OUT THE INVENTION

Hereinafter, embodiments of the present invention will be described in detail with reference to the drawings etc.

### Embodiment 1

In the present embodiment, an acidic copper plating solution of the present invention will be described.

The acidic copper plating solution of the present invention includes: a first additive including a cationic polymer; at least one second additive selected from the group consisting of 2-mercapto-5-benzimidazole sulfonic acid, sodium 2-mercapto-5-benzimidazole sulfonate dihydrate, ethylene thiourea, and partial 2-mercapto-5-benzimidazole sulfonate of poly(diallyldimethylammonium chloride); and a third additive including a sulfur atom-containing organic compound, the acidic copper plating solution having a copper concentration of 10 to 60 g/L and a sulfuric acid concentration of 10 to 200 g/L, and containing chloride ions of in an amount of 90 mg/L or less.

The cationic polymer to be used as the first additive is not particularly limited as long as it is a polymer having a cationic group in the molecule. Examples of the cationic group may include a primary amine group, a secondary amine group, a tertiary amine group and a quaternary ammonium group. Examples of the polymer containing a primary, secondary or tertiary amine group in the molecule (also referred to as a primary, secondary or tertiary amine salt polymer) may include polydiallylamine salts, polyallylamine salts, and polyethyleneimine. In addition, examples of the polymer containing a quaternary ammonium group in the molecule (also referred to as a quaternary ammonium salt polymer) may include homopolymers of poly(diallyldimethylammonium chloride) or copolymers thereof, with the copolymers including copolymers of diallyldimethylammonium chloride and sulfur dioxide. As a composition of the copolymer, the molar ratio of diallyldimethylammonium chloride:sulfur dioxide is 0.5:0.5 to 0.95:0.05. Preferably, the molar ratio is 0.5:0.5. A plurality of cationic polymers can also be used as the first additive. For example, a primary, secondary or tertiary amine salt polymer may be used together with a quaternary ammonium salt polymer. In addition, a homopolymer of a quaternary ammonium salt polymer may be used together with a copolymer thereof.

The concentration of the first additive is 1 to 50 mg/L, preferably 2 to 20 mg/L. This is because the thermal expansion coefficient hardly decreases either when the concentration of the first additive is less than 1 mg/L or when the concentration of the first additive is more than mg/L. In addition, the molecular weight of the quaternary ammonium salt polymer is preferably in a range of 1,000 to 100,000 in terms of a number average molecular weight. A copolymer of poly(diallyldimethylammonium chloride), diallyldimethylammonium chloride, and sulfur dioxide is commercially available, and in the present invention, the commercially available product thereof can also be used. Examples of the poly(diallyldimethylammonium chloride) may include PAS-H-1L and PAS-5L (manufactured by NITTOBO MEDICAL CO., LTD.). Examples of the copolymer of diallyldimethylammonium chloride and sulfur dioxide may include PAS-A-1 and PAS-A-5 manufactured by NITTOBO MEDICAL CO., LTD.

As the second additive, at least one compound selected from the group consisting of 2-mercapto-5-benzimidazole sulfonic acid, sodium 2-mercapto-5-benzimidazole sulfonate dihydrate, ethylene thiourea, and partial 2-mercapto-5-benzimidazole sulfonate of poly(diallyldimethylammonium chloride) is used. The second additive is preferably 2-mercapto-5-benzimidazole sulfonic acid, sodium 2-mercapto-5-benzimidazole sulfonate dihydrate, and partial 2-mercapto-5-benzimidazole sulfonate of poly(diallyldimethylammonium chloride), more preferably partial 2-mercapto-5-benzimidazole sulfonate of poly(diallyldimethylammonium chloride). The concentration of the second additive is 0.1 to 100 mg/L, preferably 1 to 50 mg/L. This is because the thermal expansion coefficient hardly decreases either when the concentration of the second additive is less than 0.1 mg/L or when the concentration of the second additive is more than 100 mg/L.

The partial 2-mercapto-5-benzimidazole sulfonic acid salt of poly (diallyldimethylammonium chloride) is one in which some of chloride ions as counter ions of poly(diallyldimethylammonium chloride) are substituted with 2-mercapto-5-benzimidazole sulfonic acid ions. The substitution ratio thereof is preferably in a range of 90:10 to 50:50 in terms of molar ratio of chloride compound:2-mercapto-5-benzimidazole sulfonate.

As the third additive, a sulfur atom-containing organic compound is used. As the sulfur atom-containing organic compound, one or more known sulfur atom-containing organic compounds that are used as an accelerator for increasing a plating deposition rate in acidic copper plating can be used. The sulfur atom-containing organic compound to be used in the present invention is an organic compound containing one or more sulfur atoms, and may be, for example, at least one compound selected from the group consisting of a (di)alkanesulfonic acid and a salt thereof, a mercaptoalkanesulfonic acid and a salt thereof, an aromatic sulfonic acid and a salt thereof, a bis-(sulfoalkyl)disulfide and a salt thereof, and a dialkyldithiocarbamic acid and a salt thereof. Examples of the (di)alkanesulfonic acid may include ethanesulfonic acid, propanesulfonic acid, and dipropanesulfonic acid. Examples of the mercaptoalkanesulfonic acid may include mercaptoethylsulfonic acid and mercaptopropanesulfonic acid. Examples of the aromatic sulfonic acid may include p-toluenesulfonic acid, m-xylenesulfonic acid and polystyrenesulfonic acid. Examples of the bis-(sulfoalkyl)disulfide may include bis-(sulfopropyl)disulfide. Examples of the dialkyldithiocarbamic acid may include N,N-dimethyl-dithiocarbamylpropanesulfonic acid.

The concentration of the third additive is 0.1 to 100 mg/L, preferably 0.5 to 50 mg/L. This is because the thermal expansion coefficient hardly decreases either when the concentration of the third additive is less than 0.5 mg/L or when the concentration of the third additive is more than 50 mg/L.

When a copolymer of poly(diallyldimethylammonium chloride) and/or diallyldimethylammonium chloride and sulfur dioxide is used as the first additive, the second additive may be any of 2-mercapto-5-benzimidazole sulfonic acid, 2-mercapto-5-benzimidazole sodium sulfonate dihydrate, ethylenethiourea and partial 2-mercapto-5-benzimidazole sulfonate of poly(diallyldimethylammonium chloride), but the second additive is preferably a combination of poly(diallyldimethylammonium chloride) and partial 2-mercapto-5-benzimidazole sulfonate of poly(diallyldimethylammonium chloride). By combining poly(diallyldimethylammonium chloride) with partial 2-mercapto-5-benzimidazole sulfonate of poly(diallyldimethylammonium chloride), an acidic copper plated product which is more hardly thermally expanded, i.e. an acidic copper plated product having a smaller thermal expansion coefficient can be produced.

As a copper ion source to be used in the acidic copper plating solution of the present invention, various inorganic copper salts and organic copper salts to be used in an acidic copper plating solution can be used, but copper sulfate pentahydrate is preferable. In order to reduce the thermal expansion coefficient, the copper concentration in the plating solution is 10 to 60 g/L, preferably 15 to 55 g/L, the concentration of sulfuric acid to be used for dissolving the copper salt is 10 to 200 g/L, preferably 25 to 180 g/L, and the chloride ion concentration is 90 mg/L or less and more than 0, preferably 1 to 70 mg/L.

By using the acidic copper plating solution of the present invention, an acidic copper plated product having a lower thermal expansion coefficient and a lower thermal expansion property as compared with the conventional plated copper can be produced. The acidic copper plating solution of the present invention can be used for a copper material for an electronic device which is required to have low thermal expansion property. Mention may be made of, for example, TSV, copper wiring of a glass substrate for a circuit, a copper foil for a copper-clad laminate, a copper wiring for a semiconductor, and a copper heat radiation plate and the like.

### Second Embodiment 2

In the present embodiment, an acidic copper plated product obtained by electroplating using the acidic copper plating solution of the present invention will be described.

The acidic copper plated product of the present invention has a large lattice constant at room temperature as compared to a conventional acidic copper plated product. For example, the lattice constant is larger than 3.6147 Å. The lattice constant of the acidic copper plated product of the present invention is preferably 3.6147 Å to 3.62 Å.

Further, the acidic copper plated product of the present invention has a smaller thermal expansion coefficient as compared to a conventional acidic copper plated product. Conventional plated copper has a thermal expansion coefficient of 1.70×10⁻⁵/K, and takes a constant value that does not depend on a temperature. On the other hand, the acidic copper plated product of the present invention has a thermal expansion coefficient smaller than that of conventional plated copper at a certain temperature or higher temperature, or within a certain temperature range. Hereinafter, aspects of the acidic copper plated product of the present invention will be described with regard to the lower limit temperature and the upper limit temperature of the heat treatment temperature or operating temperature of the acidic copper plated product. An acidic copper plated product of an aspect always has a thermal expansion coefficient smaller than that of conventional plated copper at a temperature within a range from the lower limit temperature to the upper limit temperature (aspect 1). In addition, the acidic copper plated product of another aspect has a thermal expansion coefficient smaller than that of conventional plated copper at a temperature up to a certain middle temperature between the lower limit temperature and the upper limit temperature, but has a thermal expansion coefficient larger than that of conventional plated copper at a temperature above the middle temperature (aspect 2). In addition, an acidic copper plated product of another aspect has a thermal expansion coefficient smaller than that of conventional plated copper only at a temperature within a range between the lower limit temperature and the upper limit temperature (aspect 3). In addition, the acidic copper plated product of another aspect has a thermal expansion coefficient smaller than that of conventional plated copper at a temperature up to a certain middle temperature between the lower limit temperature and the upper limit temperature, and has a thermal expansion coefficient of 0 or less (shrinks) at a temperature above the middle temperature (aspect 4). In addition, in another aspect, an acidic copper plated product has a thermal expansion coefficient larger than that of conventional plated copper at a temperature up to a certain middle temperature between the lower limit temperature and the upper limit temperature, and has a small thermal expansion coefficient of 0 or less (shrinks) at a temperature above the middle temperature (aspect 5). Here, the lower limit temperature is 0° C. to 100° C., and the upper limit temperature is 600° C. to 800° C. The combination of the lower limit temperature and the upper limit temperature is 0° C. to 800° C., preferably 100° C. to 600° C. The certain temperature range, in which the thermal expansion coefficient of the acidic copper plated product is smaller than that of conventional plated copper, is not particularly limited as long as it is within a middle temperature range between the lower limit temperature and the upper limit temperature, but, for example, when the combination of the lower limit temperature and the upper limit temperature is 100° C. to 600° C., the certain temperature range is a range of 100° C. or higher and lower than 500° C., 100° C. or higher and lower than 400° C., 100° C. or higher and lower than 300° C., 100° C. or higher and lower than 200° C., 200° C. or higher and lower than 600° C., 200° C. or higher and lower than 500° C., 200° C. or higher and lower than 400° C., 200° C. or higher and lower than 300° C., 300° C. or higher and lower than 600° C., 300° C. or higher and lower than 500° C., 300° C. or higher and lower than 400° C., 400° C. or higher and lower than 600° C., 400° C. or higher and lower than 500° C., or 500° C. or higher and lower than 600° C.

For example, the acidic copper plated products of the present invention include those having a thermal expansion coefficient of 1.58×10⁻⁵/K or less at 200° C. In addition, the acidic copper plated products of the present invention include those having a thermal expansion coefficient of 1.55×10⁻⁵/K or less at 400° C. The acidic copper plated products of the present invention include those having a thermal expansion coefficient of 1.58×10⁻⁵/K or less at 200° C. and a thermal expansion coefficient of 1.55×10⁻⁵/K or less at 400° C. Further, the acidic copper plated products of the present invention include those that have a negative thermal expansion coefficient and shrink at a certain temperature or higher temperature.

In addition, it is preferable that the acidic copper plated product of the present invention has a high carbon content after heat treatment. This is because the thermal expansion coefficient tends to decrease. For example, the carbon content after heat treatment at 450° C. is 0.005% by weight or more, preferably 0.01% by weight or more, more preferably 0.015% by weight or more. As the carbon content, a value measured by high-frequency combustion infrared absorption spectrometry can be employed.

Here, a method for measuring a thermal expansion coefficient as used in the present invention will be described. For the measurement, an expansion measurement apparatus (model: TD 5000 SA/25/15) manufactured by NETZSCH Japan K.K. is used. For the measurement sample, a pipe-like sample produced by the following procedure is used.

### 1. Preparation of Cathode Electrode for Copper Plating

An Au film having a thickness of 15 nm is formed by sputtering over a length of about 15 mm on the surface of an aluminum pipe having an outer diameter of 4 mm, a thickness of 0.2 mm and a length of 100 mm.

### (Copper Plating)

An aluminum pipe with an Au film in which the upper part is masked with a fluororesin tape is immersed in the acidic copper plating solution of the present invention to obtain a cathode, and copper was deposited on the Au film at a constant current of 5 to 100 mA/cm². As a power source, a DC power source PMX18-2 Å manufactured by KIKUSUI ELECTRONICS CORP. is used, and for stirring of the plating solution, a magnet pump (IWAKI MD-15R-N) manufactured by IWAKI CO., LTD. is used. In addition, the plating area of the surface of the aluminum pipe is set to (1.5×0.4 l×π)=1.88 cm² by adjustment with a masking tape.

### (Dissolution of Aluminum)

An aluminum pipe with copper deposited on the surface thereof is immersed in a 100 g/L sodium hydroxide solution to dissolve aluminum, thereby obtaining a pipe composed of a copper plated product and having an inner diameter of 4 mm, a thickness of about 20 μm and a length of 15 mm (hereinafter, abbreviated as copper plated product pipe).

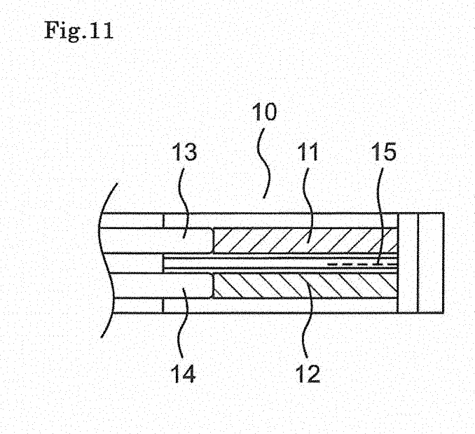

Using a quartz rod 11 as a standard sample, the thermal expansion coefficient is measured in a temperature range from room temperature to 500° C. with the prepared copper plated product pipe 12 mounted in a measurement cell shown in the plan view of FIG. 11. As the sample (copper plated product pipe) 12 is thermally expanded, the detection rod 14 that is in contact with the sample 12 is displaced, and the displacement is optically detected. The load of the detection rods 13 and 14 for pressing the standard sample 11 and the sample 12 is set to 1.0 g, and the measurement is performed in an argon atmosphere. A measuring cell is mounted in an oven (not illustrated).

The acidic copper plated product of the present invention can be used for a copper material for an electronic device which is required to have low thermal expansion property. Mention may be made of, for example, TSV, copper wiring of a glass substrate for a circuit, a copper foil for a copper-clad laminate, a copper wiring for a semiconductor, and a copper heat radiation plate and the like.

### Embodiment 3

In the present embodiment, a method for producing a semiconductor device having a through silicon via using the acidic copper plating solution of the present invention will be described.

A method for producing a semiconductor device having the through silicon via according to the present invention includes the step of preparing the through silicon via, the through silicon via preparing step including the steps of: forming a non-through via on one main surface of a silicon substrate with a transistor formed on the one main surface; plating at least the non-through via with copper by electroplating using an acidic copper plating solution according to claim 1; and forming the through silicon via by polishing the other main surface of the silicon substrate to expose copper filled into the non-through via.

In addition, in this production method, the non-through via can be filled with copper in the copper plating step.

The semiconductor device produced in this production method is not particularly limited as long as it is a device including TSV, and examples thereof include those obtained by laminating LSI chips with TSV, and those obtained using TSV on a glass substrate.

The opening diameter of the non-through via is 0.5 to 100 μm, preferably 1 to 50 μm. In addition, the depth of the non-through via is 1 to 1000 μm, preferably 2 to 500 μm. The aspect ratio is 0.1 to 100, preferably 1 to 40.

As the electroplating conditions in the step of filling copper by electroplating, the bath temperature is from room temperature to 99° C., preferably 20 to 40° C. As an energization method, direct current electrolysis or PR electrolysis (periodic current reversal electrolysis) can be employed. The current density is 0.1 to 800 mA/cm², preferably 1 to 200 mA/cm². The plating time depends on the diameter and the depth of the via, but it is preferably 20 to 300 minutes. In addition, the anode is not particularly limited as long as it is used for acidic copper plating, and a soluble electrode or an insoluble electrode can be used. In addition, a general method such as aeration or jetting can be used for stirring the plating solution.

According to this production method, pumping can be prevented even when heating to 400 to 600° C. is performed in formation of the insulating oxide film because the thermal expansion coefficient of the acidic copper plated product that forms TSV is small. This makes it possible to prevent pumping of TSV without increasing the number of heating steps and CMP steps.

### Embodiment 4

While a method for producing a semiconductor device having a through silicon via using a via middle process has been described in embodiment 3, the acidic copper plating solution of the present invention can also be used in a method for producing a semiconductor device having a through silicon via using a via last process and a via last back side process.

That is, another method for producing a semiconductor device having the through silicon via according to the present invention includes the step of preparing a through silicon via, the through silicon via preparing step including the steps of: forming a through via hole on one main surface of a silicon substrate with a transistor and a wiring layer formed on the other main surface; and plating at least the through via hole with copper by electroplating using an acidic copper plating solution of the present invention.

In addition, in this production method, the through via hole can be filled with copper in the copper plating step.

In this production method, the opening diameter, the depth, and the aspect ratio of the through via hole can be set to the same values as those of the non-through via in embodiment 3. In addition, the electroplating conditions are the same as in embodiment 3. In addition, the semiconductor device to be produced is the same as in embodiment 3.

According to this production method, pumping of TSV can be prevented even at a solder reflow temperature because the thermal expansion coefficient of the acidic copper plated product that forms TSV is small.

### Embodiment 5

In the present embodiment, a method for producing a printed circuit board using the acidic copper plating solution of the present invention will be described.

A method for producing a printed circuit board according to the present invention includes the steps of: forming an opening section on an upper surface of a substrate having a copper foil on a lower surface thereof, the opening section extending to the copper foil; forming a conductive underlayer on the upper surface of the substrate and the opening section; then forming a copper wiring layer on a surface of the underlayer by electroplating using the acidic copper plating solution according to claim 1; and patterning the copper wiring layer.

In addition, in this production method, the step of forming a copper wiring layer may include filling the opening section with copper.

As electroplating conditions, the bath temperature is from room temperature to 99° C., preferably 20 to 40° C. In addition, direct current electrolysis can be used as the energization method. The current density is 0.1 to 800 mA/cm², preferably 1 to 500 mA/cm². The plating time is preferably 20 to 300 minutes. In addition, the anode is not particularly limited as long as it is used for acidic copper plating, and a soluble electrode or an insoluble electrode can be used. In addition, a general method such as aeration or jetting can be used for stirring the plating solution.

In printed circuit boards, demand for finer pitches has been increased with demands for miniaturization and thinning of electronic devices in recent years. However, at a solder reflow temperature during mounting of components, the wiring substrate may be warped by thermal expansion of copper wiring, leading to occurrence of a connection failure due to contact between solder bumps. On the other hand, when the acidic copper plating solution of the present invention is used, it is possible to suppress warping of a wiring substrate.

### Embodiment 6

In the present embodiment, another method for producing a printed circuit board using the acidic copper plating solution of the present invention will be described.

A method for producing a printed circuit board according to the present invention includes the steps of: forming an opening section on an upper surface of a substrate having a copper foil on a lower surface thereof, the opening section extending to the copper foil; forming a conductive underlayer on the upper surface of the substrate and the opening section; forming a resist layer having a predetermined shape on the underlayer; then forming a copper wiring layer on a surface of the underlayer exposed from the resist layer by electroplating using the acidic copper plating solution according to claim 1; and then removing the resist layer and the underlayer.

In addition, in this production method, the step of forming a copper wiring layer may include filling the opening section with copper.

In addition, as electroplating conditions of this production method, the same conditions as in embodiment 5 can be employed.

In this production method, warpage of the wiring substrate by thermal expansion of copper wiring at a solder reflow temperature during mounting of components can be suppressed by using the acidic copper plating solution of the present invention as in the case of embodiment 5.

### EXAMPLES

Hereinafter, the present invention will be described more in detail by way of examples, but the present invention is not limited to the following examples.

### (Preparation of Acidic Copper Plating Solution)

The compositions of acidic copper plating solutions used in examples and comparative examples are shown in Tables 1 to 10. The abbreviations and sources of additives used are as follows.

SPS: bis-(sulfopropyl)disulfide (manufactured by Aldrich Co. LLC.)
PD-1H: polystyrene sulfonic acid
PDSH: 1,3-propanedisulfonic acid
SDDACC: poly(diallyldimethylammonium chloride) (manufactured by NITTOBO MEDICAL CO., LTD.)
NMDSC: copolymer of diallyldimethylammonium chloride and sulfur dioxide (manufactured by NITTOBO MEDICAL CO., LTD.)
2M5S: 2-mercapto-5-benzimidazole sulfonic acid (manufactured by Wako Pure Chemical Industries, Ltd.)
ETU: ethylenethiourea (manufactured by Wako Pure Chemical Industries, Ltd.)
A2M5S: Partial 2-mercapto-5-benzimidazole sulfonate of poly(diallyldimethylammonium chloride) (manufactured by NITTOBO MEDICAL CO., LTD.) (chloride: 2-mercapto-5-benzimidazole sulfonate=75:25)
MB1: sodium 2-mercapto-5-benzimidazole sulfonate dihydrate (manufactured by Wako Pure Chemical Industries, Ltd.)

TABLE 1

| | | Example 1 | Example 2 | Example 3 | Example 4 | Example 5 | Example 6 | Example 7 | Example 8 | Example 9 |
|---|---|---|---|---|---|---|---|---|---|---|
| Basic bath | CuSO₄•5H₂O | 200 | 200 | 200 | 200 | 200 | 200 | 200 | 200 | 200 |
| (g/L) | (copper concentration) | (50.9) | (50.9) | (50.9) | (50.9) | (50.9) | (50.9) | (50.9) | (50.9) | (50.9) |
| | H₂SO₄ | 25 | 25 | 25 | 25 | 25 | 25 | 25 | 25 | 25 |
| Additives | Cl— | 10 | 10 | 7 | 7 | 10 | 7 | 7 | 7 | 7 |
| (mg/L) | SPS | 2 | 2 | 2 | 2 | 2 | 2 | 2 | 2 | 2 |
| | SDDACC | 1.5 | 1.5 | 1.5 | 1.5 | 1.5 | 1.5 | 1.5 | 1.5 | 1.5 |
| | NMDSC | — | — | — | — | — | — | — | — | — |
| | 2M5S | 50 | — | — | — | — | — | — | — | — |
| | ETU | — | 5 | — | — | — | — | — | — | — |
| | A2M5S | — | — | 5 | 5 | 5 | 0.5 | 0.5 | 0.5 | 0.5 |
| Current density (mA/cm²) | | 10 | 100 | 10 | 20 | 50 | 10 | 20 | 50 | 100 |
| Result: Thermal expansion | | | | | | | | | | |
| coefficient (×10⁻⁵/K) | | | | | | | | | | |
| | 200° C. | 1.54 | 1.48 | 1.32 | 1.54 | 1.38 | 1.56 | 1.03 | 1.44 | 1.56 |
| | 400° C. | 1.53 | — | 1.18 | 0.535 | — | — | — | — | — |

TABLE 2

| | | | | | | | | Comparative |
|---|---|---|---|---|---|---|---|---|
| | | Example 10 | Example 11 | Example 12 | Example 13 | Example 14 | Example 15 | Example 1 |
| Basic bath | CuSO₄•5H₂O | 70 | 70 | 70 | 70 | 200 | 200 | 20 |
| (g/L) | (copper concentration) | (17.8) | (17.8) | (17.8) | (17.8) | (50.9) | (50.9) | (50.9) |
| | H₂SO₄ | 180 | 180 | 180 | 180 | 25 | 25 | 25 |
| Additives | Cl— | 70 | 70 | 10 | 10 | 10 | 10 | 10 |
| (mg/L) | SPS | 5 | 2 | 2 | 2 | 2 | 2 | 2 |
| | SDDACC | 8 | 8 | — | — | — | 1.5 | 1.5 |
| | NMDSC | 8 | 8 | 8 | 8 | — | — | — |
| | 2M5S | 50 | 50 | — | — | — | 50 | — |
| | ETU | — | — | — | — | 5 | — | — |
| | A2M5S | — | — | 5 | 5 | — | — | — |
| Current density (mA/cm²) | | 10 | 20 | 20 | 40 | 3 | 3 | 10 |
| Result: Thermal expansion | | | | | | | | |
| coefficient (×10⁻⁵/K) | | | | | | | | |
| | 200° C. | 1.54 | 1.58 | 1.54 | 1.40 | 1.70 | 0.5 | 1.70 |
| | | | | | | | (230° C.) | |
| | 400° C. | — | — | — | — | −7.5 | — | 1.70 |

TABLE 3

| | | | | | Comparative | | |
|---|---|---|---|---|---|---|---|
| | | Example 16 | Example 17 | Example 18 | Example 2 | Example 19 | Example 20 |
| Basic bath | CuSO₄•5H₂O | 200 | 200 | 70 | 300 | 200 | 200 |
| (g/L) | (copper concentration) | (50.9) | (50.9) | (17.8) | (76.4) | (50.9) | (50.9) |
| | H₂SO₄ | 25 | 25 | 25 | 25 | 80 | 180 |
| Additives | Cl— | 10 | 10 | 10 | 10 | 10 | 10 |
| (mg/L) | SPS | 5 | 5 | 5 | 5 | 5 | 5 |
| | SDDACC | — | — | — | — | — | — |
| | NMDSC | 8 | 8 | 8 | 8 | 8 | 8 |
| | 2M5S | 50 | 50 | 50 | 50 | 50 | 50 |
| | A2M5S | — | — | — | — | — | — |
| | ETU | — | — | — | — | — | — |
| Current density (mA/cm²) | | 20 | 80 | 20 | 20 | 20 | 20 |
| Result: Thermal expansion | | | | | | | |
| coefficient (×10⁻⁵/K) | | | | | | | |
| | 100° C. | 1.78 | 1.66 | 1.64 | 1.81 | 1.80 | 1.66 |
| | 200° C. | 1.58 | 1.56 | 1.20 | 1.79 | 1.70 | 1.57 |
| | 300° C. | 1.07 | 1.58 | 0.71 | 1.81 | 1.35 | 1.48 |
| | 400° C. | 2.72 | 4.41 | 3.75 | 5.45 | 3.00 | 2.41 |

TABLE 4

| | | | | | | Comparative | Comparative |
|---|---|---|---|---|---|---|---|
| | | Example 21 | Example 22 | Example 23 | Example 24 | Example 3 | Example 4 |
| Basic bath | CuSO₄•5H₂O | 200 | 200 | 200 | 200 | 200 | 200 |
| (g/L) | (copper concentration) | (50.9) | (50.9) | (50.9) | (50.9) | (50.9) | (50.9) |
| | H₂SO₄ | 25 | 25 | 25 | 25 | 25 | 25 |
| Additives | Cl— | 1 | 5 | 30 | 70 | — | 100 |
| (mg/L) | SPS | 5 | 5 | 5 | 5 | 5 | 5 |
| | SDDACC | — | — | — | — | — | — |
| | NMDSC | 8 | 8 | 8 | 8 | 8 | 8 |
| | 2M5S | 50 | 50 | 50 | 50 | 50 | 50 |
| | A2M5S | — | — | — | — | — | — |
| | ETU | — | — | — | — | — | — |
| Current density (mA/cm²) | | 20 | 20 | 20 | 20 | 20 | 20 |
| Result: Thermal expansion | | | | | | | |
| coefficient (×10⁻⁵/K) | | | | | | | |
| | 100° C. | 1.70 | 1.75 | 1.82 | 1.73 | 1.70 | 1.71 |
| | 200° C. | 1.58 | 1.68 | 1.81 | 1.71 | 1.74 | 1.71 |
| | 300° C. | 1.62 | 1.60 | 1.64 | 1.66 | 2.11 | 1.86 |
| | 400° C. | 3.19 | 3.39 | 2.94 | 3.00 | 3.63 | 4.13 |

TABLE 5

| | | Example 25 | Example 26 | Example 27 | Example 28 | Example 29 | Example 30 | Example 31 | Example 32 |
|---|---|---|---|---|---|---|---|---|---|
| Basic bath | CuSO₄•5H₂O | 200 | 200 | 200 | 200 | 200 | 200 | 200 | 200 |
| (g/L) | (copper concentration) | (50.9) | (50.9) | (50.9) | (50.9) | (50.9) | (50.9) | (50.9) | (50.9) |
| | H₂SO₄ | 25 | 25 | 25 | 25 | 25 | 25 | 25 | 25 |
| Additives | Cl— | 10 | 10 | 10 | 10 | 10 | 10 | 10 | 10 |
| (mg/L) | SPS | 2.5 | 10 | 20 | 40 | 5 | 5 | 5 | 5 |
| | SDDACC | — | — | — | — | — | — | — | — |
| | NMDSC | 8 | 8 | 8 | 8 | 2 | 8 | 8 | 8 |
| | 2M5S | 50 | 50 | 50 | 50 | 50 | 50 | 20 | 100 |
| | A2M5S | — | — | — | — | — | — | — | — |
| | ETU | — | — | — | — | — | — | — | — |
| Current density (mA/cm²) | | 20 | 20 | 20 | 20 | 20 | 20 | 20 | 20 |
| Result: Thermal expansion | | | | | | | | | |
| coefficient (×10⁻⁵/K) | | | | | | | | | |
| | 100° C. | 1.84 | 1.70 | 1.63 | 1.69 | 1.66 | 1.74 | 1.81 | 1.79 |
| | 200° C. | 1.76 | 1.48 | 1.58 | 1.60 | 1.56 | 1.59 | 1.74 | 1.64 |
| | 300° C. | 1.11 | 1.51 | 1.51 | 1.54 | 1.25 | 1.53 | 1.53 | 1.38 |
| | 400° C. | 1.75 | 1.76 | 1.76 | 1.42 | 3.49 | 3.54 | 3.93 | 3.90 |

TABLE 6

| | | Example 33 | Example 34 | Example 35 | Example 36 | Example 37 | Example 38 | Example 39 |
|---|---|---|---|---|---|---|---|---|
| Basic bath | CuSO₄•5H₂O | 200 | 200 | 200 | 300 | 200 | 200 | 200 |
| (g/L) | (copper concentration) | (50.9) | (50.9) | (50.9) | (76.4) | (50.9) | (50.9) | (50.9) |
| | H₂SO₄ | 25 | 25 | 25 | 25 | 10 | 80 | 180 |
| Additives | Cl— | 10 | 10 | 10 | 10 | 10 | 10 | 10 |
| (mg/L) | SPS | 2 | 2 | 2 | 2 | 2 | 2 | 2 |
| | SDDACC | 1.5 | 1.5 | 1.5 | 1.5 | 1.5 | 1.5 | 1.5 |
| | NMDSC | — | — | — | — | — | — | — |
| | 2M5S | — | — | — | — | — | — | — |
| | A2M5S | 5 | 5 | 5 | 5 | 5 | 5 | 5 |
| | ETU | — | — | — | — | — | — | — |
| Current density (mA/cm²) | | 20 | 20 | 20 | 20 | 20 | 20 | 20 |
| Result: Thermal expansion | | | | | | | | |
| coefficient (×10⁻⁵/K) | | | | | | | | |
| | 100° C. | 1.61 | 1.63 | 1.67 | 1.66 | 1.56 | 1.65 | 1.64 |
| | 200° C. | 1.46 | 1.64 | 1.63 | 1.58 | 1.40 | 1.46 | 1.58 |
| | 300° C. | 1.38 | 1.61 | 1.57 | 1.51 | 1.40 | 1.36 | 1.53 |
| | 400° C. | 1.47 | 1.62 | 1.75 | 1.61 | 1.58 | 1.43 | 1.53 |

TABLE 7

| | | Exam- | Exam- | Exam- | Exam- |
|---|---|---|---|---|---|
| | | ple 40 | ple 41 | ple 42 | ple 43 |
| Basic bath | CuSO₄•5H₂O | 200 | 200 | 200 | 200 |
| (g/L) | (copper concentration) | (50.9) | (50.9) | (50.9) | (50.9) |
| | H₂SO₄ | 25 | 25 | 25 | 25 |
| Additives | Cl— | 5 | 30 | 70 | 100 |
| (mg/L) | SPS | 2 | 2 | 2 | 2 |
| | SDDACC | 1.5 | 1.5 | 1.5 | 1.5 |
| | NMDSC | — | — | — | — |
| | 2M5S | — | — | — | — |
| | A2M5S | 5 | 5 | 5 | 5 |
| | ETU | — | — | — | — |
| Current density (mA/cm²) | | 20 | 20 | 20 | 20 |
| Result: Thermal expansion | | | | | |
| coefficient (×10⁻⁵/K) | | | | | |
| | 100° C. | 1.67 | 1.65 | 1.71 | 1.63 |
| | 200° C. | 1.63 | 1.60 | 1.69 | 1.65 |
| | 300° C. | 1.57 | 1.51 | 1.66 | 1.63 |
| | 400° C. | 1.75 | 1.48 | 1.63 | 1.59 |

TABLE 8

| | | Example 44 | Example 45 | Example 46 | Example 47 | Example 48 | Example 49 | Example 50 |
|---|---|---|---|---|---|---|---|---|
| Basic bath | CuSO₄•5H₂O | 200 | 200 | 200 | 200 | 200 | 200 | 200 |
| (g/L) | (copper concentration) | (50.9) | (50.9) | (50.9) | (50.9) | (50.9) | (50.9) | (50.9) |
| | H₂SO₄ | 25 | 25 | 25 | 25 | 25 | 25 | 25 |
| Additives | Cl— | 10 | 10 | 10 | 10 | 10 | 10 | 10 |
| (mg/L) | SPS | 1 | 5 | 10 | 20 | 2 | 2 | 2 |
| | SDDACC | 1.5 | 1.5 | 1.5 | 1.5 | 0.75 | 3 | 10 |
| | NMDSC | — | — | — | — | — | — | — |
| | 2M5S | — | — | — | — | — | — | — |
| | A2M5S | 5 | 5 | 5 | 5 | 5 | 5 | 5 |
| | ETU | — | — | — | — | — | — | — |
| Current density (mA/cm²) | | 20 | 20 | 20 | 20 | 20 | 20 | 20 |
| Result: Thermal expansion | | | | | | | | |
| coefficient (×10⁻⁵/K) | | | | | | | | |
| | 100° C. | 1.61 | 1.68 | 1.68 | 1.66 | 1.63 | 1.67 | 1.65 |
| | 200° C. | 1.36 | 1.67 | 1.67 | 1.66 | 1.47 | 1.64 | 1.64 |
| | 300° C. | 1.18 | 1.62 | 1.62 | 1.65 | 1.37 | 1.55 | 1.63 |
| | 400° C. | 1.21 | 1.63 | 1.63 | 1.64 | 1.43 | 1.41 | 1.62 |

TABLE 9

| | | Example 51 | Example 52 | Example 53 | Example 54 | Example 55 | Example 56 | Example 57 |
|---|---|---|---|---|---|---|---|---|
| Basic bath | CuSO₄•5H₂O | 200 | 200 | 200 | 200 | 200 | 200 | 70 |
| (g/L) | (copper concentration) | (50.9) | (50.9) | (50.9) | (50.9) | (50.9) | (50.9) | (17.8) |
| | H₂SO₄ | 25 | 25 | 25 | 25 | 25 | 25 | 180 |
| Additives | Cl— | 10 | 10 | 10 | 10 | 10 | 10 | 50 |
| (mg/L) | SPS | 2 | 2 | 2 | 8 | 2 | 2 | 2 |
| | SDDACC | 1.5 | 1.5 | 1.5 | — | 1.5 | 1.5 | 1.5 |
| | NMDSC | — | — | — | 8 | — | — | — |
| | 2M5S | — | — | — | — | — | — | — |
| | A2M5S | 1 | 2.5 | 50 | — | — | — | — |
| | ETU | — | — | — | 1 | 5 | 5 | 5 |
| Current density (mA/cm²) | | 20 | 20 | 20 | 20 | 5 | 100 | 5 |
| Result: Thermal expansion | | | | | | | | |
| coefficient (×10⁻⁵/K) | | | | | | | | |
| | 100° C. | 1.63 | 1.63 | 1.20 | 1.64 | 1.66 | 1.63 | 1.76 |
| | 200° C. | 1.62 | 1.55 | 1.16 | 1.49 | 1.63 | 1.45 | 1.46 |
| | 300° C. | 1.56 | 1.51 | 2.09 | 1.87 | 1.60 | 1.69 | 1.13 |
| | 400° C. | 1.53 | 1.50 | 4.73 | 4.04 | 2.53 | 2.07 | — |

TABLE 10

| | | Exam- | Exam- | Exam- | Exam- |
|---|---|---|---|---|---|
| | | ple 58 | ple 59 | ple 60 | ple 61 |
| Basic bath | CuSO₄•5H₂O | 200 | 70 | 200 | 200 |
| (g/L) | (copper concentration) | (50.9) | (17.8) | (50.9) | (50.9) |
| | H₂SO₄ | 25 | 180 | 25 | 25 |
| Additives | Cl— | 10 | 50 | 10 | 10 |
| (mg/L) | SPS | 2 | 5 | — | — |
| | PS—1H | — | — | 8 | — |
| | PDSH | — | — | — | 8 |
| | SDDACC | 1.5 | 1.5 | — | — |
| | NMDSC | — | — | 8 | 8 |
| | 2M5S | — | — | — | — |
| | A2M5S | — | — | — | — |
| | ETU | — | — | 5 | 5 |
| | MB1 | 1 | 1 | — | — |
| Current density (mA/cm²) | | 20 | 20 | 20 | 20 |
| Result: Thermal expansion | | | | | |
| coefficient (×10⁻⁵/K) | | | | | |
| | 100° C. | 1.65 | 1.5 | 1.62 | 1.55 |
| | 200° C. | 1.48 | 1.47 | 1.61 | 1.84 |
| | 300° C. | 1.32 | 1.37 | 1.69 | 2.01 |
| | 400° C. | 1.54 | 1.37 | 1.87 | 1.67 |

### Test Example 1 (Measurement of Thermal Expansion Coefficient)

A cathode for copper plating as described in the foregoing method for measuring a thermal expansion coefficient was used. Plating was performed at a liquid temperature of 25° C. and a current density of 10 to 100 mA/cm², and an aluminum core material was dissolved and removed to obtain a copper plated product pipe having an inner diameter of 4 mm, a thickness of about 20 μm and a length of 15 mm.

Using the foregoing expansion measurement apparatus manufactured by NETZSCH Japan K.K., the thermal expansion coefficient was measured in a temperature range from room temperature to 500° C. The measurement results are shown in Tables 1 to 10. The thermal expansion coefficient of a commercially available copper pipe was also measured in a temperature range from room temperature to 500° C., and the thermal expansion coefficient was (1.70±0.01)×10⁻⁵/K.

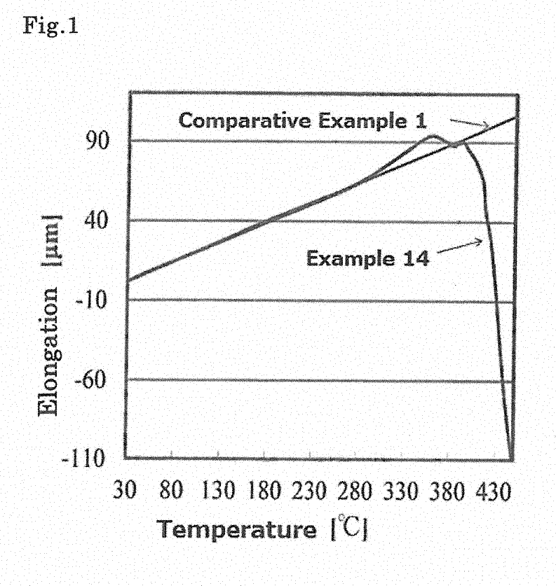

Thermal expansion coefficients in example will be described. The plating solution in Comparative Example 1 contains a first additive and a third additive, but does not contain a second additive. In Comparative Example 1, elongation increased linearly with a rise in temperature as in the case of a conventional plated copper, and the thermal expansion coefficient was 1.65×10⁻⁵/K at 200° C., and 1.70×10⁻⁵/K at 400° C. On the other hand, in Examples 1 to 13 where the plating solution included the first additive, the second additive, and the third additive, a low thermal expansion coefficient of 1.03×10⁻⁵/K to 1.58×10⁻⁵/K was obtained at 200° C. Further, when A2M5S was used as the second additive, a very low thermal expansion coefficient equivalent to about 30% of that of pure copper, i.e. 0.535×10⁻⁵/K, was obtained at 400° C. in Example 3. In Example 14, as shown in FIG. 1, the thermal expansion coefficient tends to be negative at a temperature of not lower than about 350° C., and for example, the thermal expansion coefficient is −7.5×10⁻⁵/K at 400° C.

Examples 16 to 32 and Comparative Examples 2 to 4 are experimental examples using NMDSC as the first additive, 2M5S as the second additive, and SPS as the third additive. Examples 33 to 53 are experimental examples using SDDACC as the first additive, A2M5S as the second additive, and SPS as the third additive. Examples 54 to 57 are experimental examples using ETU as the second additive. NMDSC was used as the first additive in Example 54, and SDDACC was used as the first additive in Examples 55 to 57. When the copper concentration was in a range of 10 to 60 g/L, a low thermal expansion coefficient was obtained (e.g. Examples 16, 18 and 36), but when the copper concentration was more than 60 g/L, the thermal expansion coefficient increased (Comparative Example 2). In addition, when the sulfuric acid concentration was in a range of 10 to 200 g/L, a low thermal expansion coefficient was obtained (e.g. Examples 16, 19, 20 and 37 to 39). When the chloride ion concentration was in a range of more than 0 mg/L and not more than 90 mg/L, a low thermal expansion coefficient was obtained (Examples 21 to 24 and 40 to 43, and Comparative Examples 3 and 4). In addition, even when the SPS concentration was varied over a wide range, a low thermal expansion coefficient was obtained (e.g. Examples 25 to 28 and 44 to 47). In addition, even when the A2M5S concentration was varied over a wide range, a low thermal expansion coefficient was obtained (e.g. Examples 30 to 32 and 51 to 53). When ETU was used, a low thermal expansion coefficient was obtained (Examples 54 to 57). In addition, even when the SDDACC concentration was varied over a wide range, a low thermal expansion coefficient was obtained (e.g. Examples 48 to 50). For the influence of the bath temperature, a low thermal expansion coefficient was obtained at any of room temperature (about 20° C., Example 33), 40° C. (Example 34) and 50° C. (Example 35).

In addition, when MB1 was used as the second additive, a low thermal expansion coefficient was obtained (Examples 58 and 59). In addition, when as the third additive, PS-1H was used (Example 60) or PDSH was used (Example 61), a low thermal expansion coefficient was obtained.

### Test Example 2 (Evaluation of Pumping of TSV)

Next, TSV was prepared using the acidic copper plating solution of the present invention, and pumping was evaluated for the prepared TSV.

A silicon substrate having a non-through via having an opening diameter of 6 μm and a depth of 25 μm (an aspect ratio of 4) was provided, and an underlayer having a thickness of 200 nm was formed on a surface of the silicon substrate by sputtering.

The silicon substrate provided with the underlayer was immersed in an acidic copper plating solution having the composition in Example 2, and copper plating was performed for 90 minutes under the following PR electrolysis conditions using phosphorus-containing copper as an anode. Using a plating solution having the composition in Comparative Example 1, copper plating was performed under the same PR electrolysis conditions as described above.

| | | |
|---|---|---|
| Positive electrolysis current value (Ion) | −3 | mA/cm² |
| Reverse electrolysis current value (Irev) | 18 | mA/cm² |
| Positive electrolysis time (Ton) | 200 | ms |
| Reverse electrolysis time (Trev) | 10 | ms |
| Pause time (Toff) | 200 | ms |

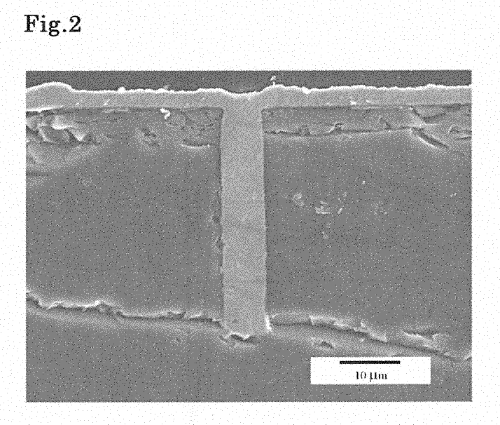

The state of a cross-section of the non-through via filled with a copper plating was observed with a scanning electron microscope (hereinafter, also referred to as SEM) (S-4300 manufactured by Hitachi, Ltd.). FIG. 2 shows a SEM photograph of the cross-section. It was confirmed that fully filled TSV free from voids was obtained.

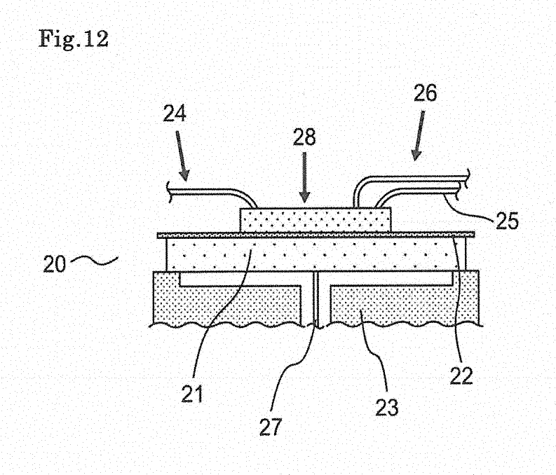

Next, the prepared TSV was fixed to a high-temperature sample stage 20 for in situ observation as shown in FIG. 12. The sample stage 20 has a ceramic support 23 that supports a ceramic heater 21 with a carbon plate 22 disposed on a surface thereof. A sample 28 is fixed on the carbon plate 22 by a pair of clamps 24 and 25. The temperature of the ceramic heater 21 is controlled by a thermocouple 27, and the temperature of the sample 28 is detected by a thermocouple 26.

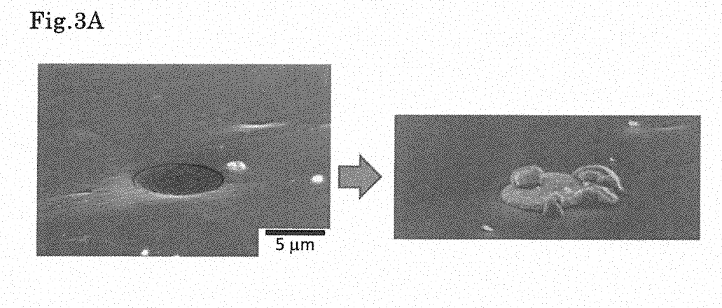

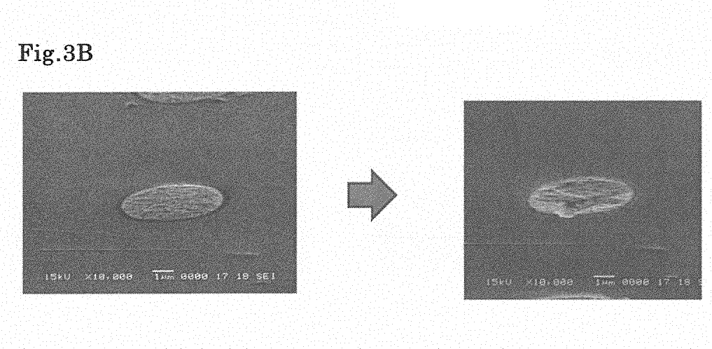

FIG. 3A shows scanning electron micrographs of TSV at room temperature (left side) and when heated to 450° C. (right side), the TSV being prepared using the plating solution of Comparative Example 1. TSV overflows a surface of the silicon substrate, and thus it is apparent that pumping occurs. On the other hand, FIG. 3B shows scanning electron micrographs of TSV at room temperature (left side) and when heated to 450° C. (right side), the TSV being prepared using the plating solution of Example 14. Swelling of TSV from the silicon substrate surface was not observed, and thus it was confirmed that pumping was suppressed.

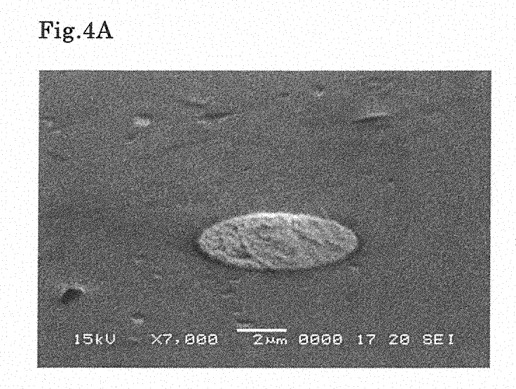

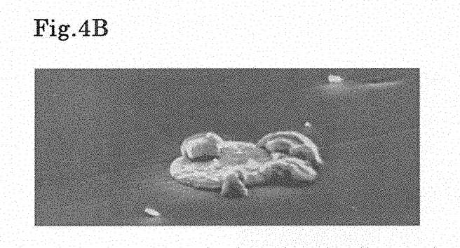

FIGS. 4A and 4B show scanning electron micrographs after heating is performed at 450° C. six times. It was found that pumping did not occur at all in TSV (FIG. 4A) prepared using the plating solution of Example 14, whereas pumping occurred in TSV (FIG. 4B) prepared using the plating solution of Comparative Example 1. TSV prepared using the plating solution of Comparative Example 1 was pumped to a height of 1.419 μm at most from the surface of the silicon substrate.

### Test Example 3 (Measurement of Electric Resistance of TSV)

A plating solution having the composition in Example 2 was used, an electrode with gold deposited on a surface of a glass plate (a size of 25×75 mm) by sputtering was used as a cathode, and phosphorus-containing copper was used as an anode to perform copper plating at a current density of 3 mA/cm². On the other hand, one obtained by performing copper plating under the same conditions as described above using a plating solution having the composition in Comparative Example 1 was used as a comparative sample. The prepared sample was subjected to the following heating treatment after the electric resistance was measured at room temperature.

Temperature elevation rate: 10° C./min

Vacuum degree: 1.5×10⁻⁵ Torr

Holding temperature: 400° C.

Retention time: 30 minutes

The electric resistance was measured at room temperature using a four terminal method. The volume resistance value of the comparative sample was 3.7×10⁻⁶ Ω·cm. On the other hand, the volume resistance value of an acidic copper plated product produced using a plating solution having the composition in Example 2 was 4.0×10⁻⁶ Ω·cm. The difference between the former and latter volume resistance values was about 9%, and the acidic copper plated product of Example 2 was confirmed to have an electric resistance comparative to that of a conventional acidic copper plated product.

### Test Example 4 (Evaluation as Wiring for Printed Circuit Board)

A copper plated product pipe prepared using the same method as in Test Example 1 was used as a sample, except that a plating solution having the composition in Example 15 was used, and the current density was 3 mA/cm². The sample was heated at 200° C. for 60 minutes, and the thermal expansion coefficient was measured. One obtained by performing copper plating under the same conditions as described above using a plating solution having the composition in Comparative Example 1 was used as a comparative sample.

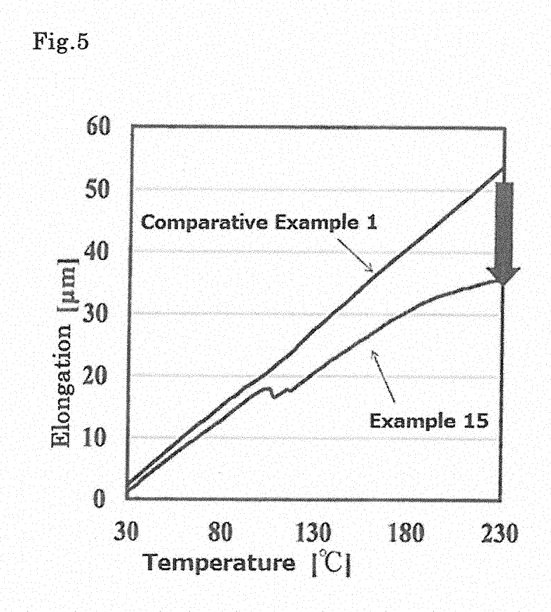

The results are shown in FIG. 5. The thermal expansion coefficient of the sample obtained using a plating solution having the composition in Example 15 was 0.5×10⁻⁵/K at 230° C., and the elongation thereof was smaller by about 34% than that of the comparative sample. Accordingly, it was confirmed that copper plated wiring capable of suppressing thermal expansion was possible at reflow temperature of solder.

In addition, using a plating solution having the composition in Example 1, a sample for measurement of the electrical resistance was prepared by the same method as in Test Example 3. In addition, using a plating solution having the composition in Comparative Example 1, a comparative sample was prepared by the same method as in Test Example 3. The prepared sample was subjected to the following heat treatment.

Temperature elevation rate: 10° C./min

Vacuum degree: 1.5×10⁻⁵ Torr

Holding temperature and holding time: at 200° C. for 60 minutes and at 230° C. for 1 minute

The electric resistance was measured at room temperature using a four terminal method. The volume resistance value of the comparative sample was 3.7×10⁻⁶ Ω·cm. On the other hand, the volume resistance value of an acidic copper plated product produced using a plating solution having the composition in Example 15 was 5.1×10⁻⁶ Ω·cm. The difference between the former and latter volume resistance values was about 39%, and the acidic copper plated product of Example 15 was confirmed to have an electric resistance comparative to that of a conventional acidic copper plated product.

### (Analysis of Acidic Copper Plated Product)

FEAES analysis and X-ray diffraction analysis were performed for the acidic copper plated product prepared using the acidic copper plating solution of the present invention. FEAES analysis was performed using a field emission Auger electron spectroscope (Model: 686) manufactured by ULVAC-PHI, INCORPORATED. For the analysis, the acidic copper plated product of Example 14 was used.

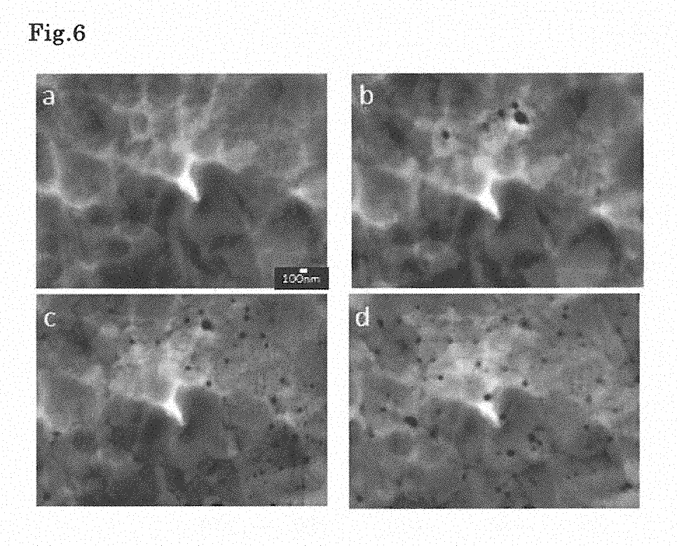

FIG. 6 shows a result of observing a structure of the acidic copper plated product of the present invention after heat treatment. Pictures a, b, c and d show results of observation of the structure when the acidic copper plated product is heated to and kept at 203° C., 310° C., 350° C. and 450° C., respectively. In the picture a, copper crystals with a grain size of about 1.0 μm can be observed. In the picture b, black structures with a grain size of about 100 μm appeared. The black structures were deposited abundantly in the vicinity of the triple point of the crystal grain boundary of copper crystals. In addition, in the pictures c and d, the number of black structures increased.

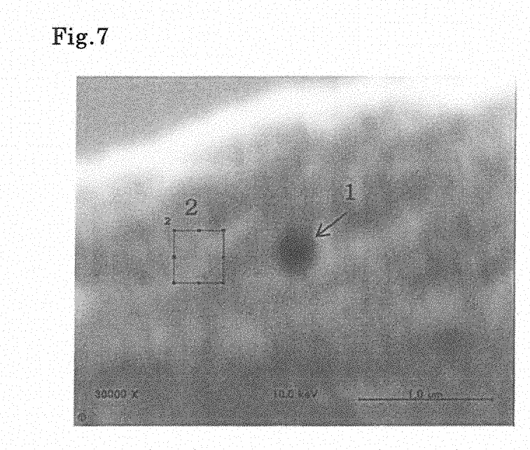

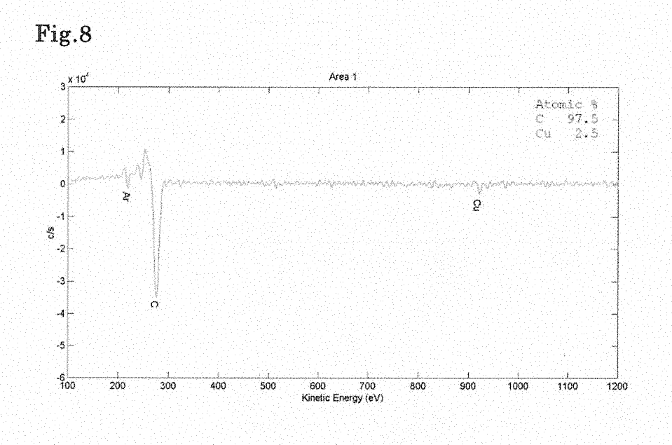

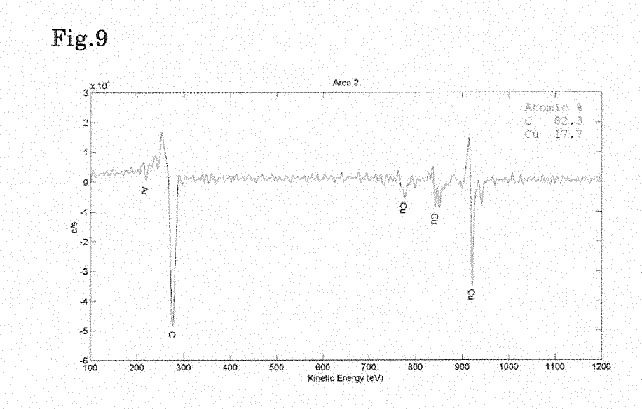

FIG. 7 shows an SEM photograph of the acidic copper plated product of the present invention which is heated to 450° C. The black spot 1 seen at the center of the photograph corresponds to black structures, and other structures correspond to copper. FIGS. 8 and 9 show results of FEAES analysis of black structures and other structures in the photograph in FIG. 7. The abscissa represents kinetic energy (eV), and the ordinate represents an intensity. The intensity of copper near 910 eV hardly appears at the black spot 1. However, the intensity of carbon near 280 eV is high. The black structure is a mass of carbon. On the other hand, in structures other than the black structures, for example in a portion indicated by reference numeral 2 in the photograph, the intensity of copper is remarkably high, and the intensity of carbon is also high. FEAES gives information on the outermost surface of a metal. And the metal easily adsorbs the carbon in the air. Thus, it is considered that the strength of carbon was high in the portion indicated by reference numeral 2.

The carbon content of the acidic copper plated product of the present invention which was heated to 450° C. was analyzed by high frequency combustion infrared absorption spectrometry using a carbon/sulfur analyzer CSLS 600 manufactured by LECO JAPAN CORPORATION, and the result showed that the carbon content was 0.018% by weight. On the other hand, the carbon content was analyzed for Comparative Example 1 in which the second additive was not used, the result showed that the carbon content was 0.004% by weight.

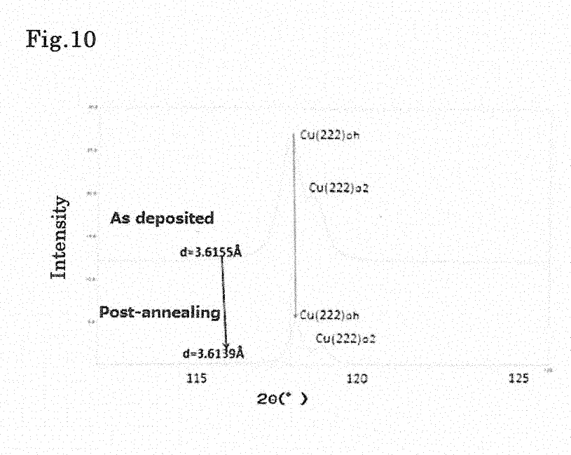

FIG. 10 is a view showing results of X-ray diffraction of an as-deposited acidic copper plated product and an acidic copper plated product after the as-deposited acidic copper plated product is annealed at 450° C. for 30 minutes (hereinafter, referred to as post-annealing). Cu(222)αh and Cu(222)α2 on the high angle side where a change in lattice constant can be considerably detected are shown. Cu(222)αh is displaced to the high angle side by about 0.3° after annealing. When the displacement of the lattice constant is expressed by a lattice constant, d=3.6155 Å in the as-deposited acidic copper-plated product and d=3.6139 Å in the post-annealing acidic copper-plated product. Thus, it is confirmed that the lattice constant decreases and the unit cell of copper shrinks.

It is considered that as-deposited copper solid-dissolves carbon in the copper unit cell. Thus, the solid solution copper is in a non-equilibrium state. With heating, the solid solution copper in a non-equilibrium state is changed to copper in an equilibrium state which does not solid-dissolve carbon. This carbon is diffused, and deposited at the triple point of the copper grain boundary (FIGS. 6b, 6c and 6d and black structures in FIG. 7). Shrinkage of the unit cell from non-equilibrium copper to equilibrium copper, which is associated with the heat treatment, is considered to form a mechanism in which copper having a thermal expansion coefficient lower than that of a conventional plated copper is developed.

### INDUSTRIAL APPLICABILITY

According to the present invention, it is possible to provide an acidic copper plating solution capable of suppressing thermal expansion of a copper plated product. Accordingly, there can be provided a copper material for an electronic device such as wiring or a heat radiation plate, which is required to have low thermal expansion property.

### DESCRIPTION OF REFERENCE NUMERALS

10 Measurement cell
11 Quartz rod
12 Copper plated product pipe
13, 14 Detection rod
20 Sample Stage
21 Ceramic heater
22 Carbon plate
23 Ceramic support
24, 25 Clamp
26, 27 Thermocouple
28 Sample

1. An acidic copper plating solution comprising:
a first additive including a cationic polymer;
at least one second additive selected from the group consisting of 2-mercapto-5-benzimidazole sulfonic acid, sodium 2-mercapto-5-benzimidazole sulfonate dihydrate, ethylene thiourea, and partial 2-mercapto-5-benzimidazole sulfonate of poly(diallyldimethylammonium chloride); and
a third additive including a sulfur atom-containing organic compound,
the acidic copper plating solution having a copper concentration of 10 to 60 g/L and a sulfuric acid concentration of 10 to 200 g/L, and containing chloride ions of in an amount of 90 mg/L or less.

2. The acidic copper plating solution according to claim 1, wherein the first additive is a quaternary ammonium salt polymer.

3. The acidic copper plating solution according to claim 2, wherein the first additive is poly (diallyldimethylammonium chloride) or a copolymer of diallyldimethylammonium chloride and sulfur dioxide.

4. The acidic copper plating solution according to claim 1, wherein the second additive is partial 2-mercapto-5-benzimidazole sulfonate of poly (diallyldimethylammoniumchloride).

5. The acidic copper plating solution according to claim 1, wherein the third additive is at least one compound selected from the group consisting of a (di)alkanesulfonic acid and a salt thereof, a mercaptoalkanesulfonic acid and a salt thereof, an aromatic sulfonic acid and a salt thereof, a bis-(sulfoalkyl)disulfide and a salt thereof, and a dialkyldithiocarbamic acid and a salt thereof.

6. An acidic copper plated product having a lattice constant of more than 3.6147 Å at room temperature, and a carbon content of 0.005% by weight or more after heat treatment at 450° C.

7. The acidic copper plated product according to claim 6, wherein the thermal expansion coefficient at 200° C. is 1.58×10⁻⁵/K or less.

8. The acidic copper plated product according to claim 6, wherein the thermal expansion coefficient at 400° C. is 1.55×10⁻⁵/K or less.

9. The acidic copper plated product according to claim 6, wherein the acidic copper plated product is a through silicon via.

10. A method for producing a semiconductor device, the method comprising a step of preparing a through silicon via,
the through silicon via preparing step including the steps of:
forming a non-through via on one main surface of a silicon substrate with a transistor formed on the one main surface;
plating at least the non-through via with copper by electroplating using the acidic copper plating solution according to claim 1; and
forming the through silicon via by polishing the other main surface of the silicon substrate to expose copper filled into the non-through via.

11. A method for producing a semiconductor device, the method comprising the step of preparing a through silicon via,
the through silicon via preparing step including the steps of:
forming a through via hole on one main surface of a silicon substrate with a transistor and a wiring layer formed on the other main surface; and
plating the through via hole with copper by electroplating using the acidic copper plating solution according to claim 1.

12. The method for producing a semiconductor device according to claim 10, wherein the non-through via or the through via hole is filled with copper in the copper plating step.

13. A method for producing a printed circuit board, the method comprising the steps of:
forming an opening section on an upper surface of a substrate having a copper foil on a lower surface thereof, the opening section extending to the copper foil;
forming a conductive underlayer on the upper surface of the substrate and the opening section;
then forming a copper wiring layer on a surface of the underlayer by electroplating using the acidic copper plating solution according to claim 1; and
patterning the copper wiring layer.

14. A method for producing a printed circuit board, the method comprising the steps of:
forming an opening section on an upper surface of a substrate having a copper foil on a lower surface thereof, the opening section extending to the copper foil;
forming a conductive underlayer on the upper surface of the substrate and the opening section;
forming a resist layer having a predetermined shape on the underlayer;
then forming a copper wiring layer on a surface of the underlayer exposed from the resist layer by electroplating using the acidic copper plating solution according to claim 1; and
then removing the resist layer and the underlayer.

15. The method for producing a printed circuit board according to claim 13, wherein the opening section is filled with copper in the step of forming the copper wiring layer.
